(19) United States
(12) Patent Application Publication
(10) Pub. No.: US 2015/0361579 A1
(43) Pub. Date: Dec. 17, 2015

(54) SAPPHIRE SINGLE CRYSTAL CORE AND PRODUCTION METHOD THEREOF

(71) Applicant: Tokuyama Corporation, Shunan-shi, Yamaguchi (JP)

(72) Inventors: Naoto MOCHIZUKI, Shunan-shi (JP); Yuichi IKEDA, Shunan-shi (JP); Katsuya OGAWA, Shunan-shi (JP)

(73) Assignee: TOKUYAMA CORPORATION, Shunan-shi, Yamaguchi (JP)

(21) Appl. No.: 14/763,675

(22) PCT Filed: Feb. 7, 2014
(86) PCT No.: PCT/JP2014/053568

§ 371 Date: Jul. 27, 2015

(30) Foreign Application Priority Data
Feb. 25, 2013 (JP) 2013-034581

(51) Int. Cl. C30B 15/22; C30B 29/20

(52) U.S. Cl. CPC C30B 15/22; C30B 29/20

(57) ABSTRACT

A sapphire single crystal core having an r-axis direction, a length of 200 mm or more and a diameter of 150 mm or more and containing no air bubbles, and a method of producing the sapphire single crystal core, comprising the steps of:
obtaining a sapphire ingot by growing a sapphire single crystal in an r-axis direction by the Czochralski method; and
cutting out the core from the sapphire ingot, wherein
when the shoulder part of the ingot was formed by the Czochralski method, the shoulder part forming speed is controlled to ensure that the length in the growth direction of an area where the angle with respect to the horizontal plane is 10 to 30° of the shoulder part becomes 10 mm or less.

### TECHNICAL FIELD

The present invention relates to a sapphire single crystal core and a production method thereof.

The above sapphire single crystal core is mainly used as a material for an insulating substrate for use in an SOS substrate. The production method of the above sapphire single crystal core is a method of producing a sapphire single crystal core from which an insulating substrate for use in an SOS substrate can be cut out with high yield and which contains no air bubbles.

### BACKGROUND ART

An SOI (Silicon On Insulator) substrate is obtained by growing a silicon film on an insulating substrate material. A semiconductor device formed on this SOI substrate enables high-speed operation and the high integration of circuits as compared with a device formed on a single crystal silicon substrate. Under the circumstances, the commercialization of the SOI substrate as a substrate for high-performance devices is gradually progressing.

As a typical example of this SOI substrate, there is known an SOS (Silicon On Sapphire) substrate which is obtained by growing a silicon film on a sapphire (aluminum oxide) single crystal substrate.

The SOS substrate can be formed by the epitaxial growth of silicon on the r-plane (mirror index {1-102}) of a sapphire substrate by CVD or MBE. Since the sapphire r-plane has a small difference in lattice constant from that of silicon, silicon is easily epitaxially grown on this plane. As the r-plane sapphire substrate used herein, a substrate having a diameter of 150 mm (people having ordinary skill in the art generally call this “6-inch substrate”) or a substrate having a larger diameter than this is required.

The development of sapphire substrate mass-production technology is now actively under way. This is because demand for a sapphire substrate for forming the nitride semiconductor of an LED chip is growing. As a substrate for forming a nitride semiconductor, a c-plane (mirror index {0001}) sapphire substrate having the smallest difference in lattice constant from that of a nitride semiconductor is used. Therefore, the development of the above mass-production technology is mainly specialized in the efficient production of the c-plane sapphire substrateh. Meanwhile, no progress has been made in the research and development of technology for producing a large-diameter r-plane sapphire substrate having a large diameter of 6 inches or more which is used in an SOS substrate.

As a method of producing a sapphire ingot (single crystal) which becomes the material of a sapphire single crystal substrate, there are known Verneuil method, EFG (Edge-defined Film-fed Growth) method, Czochralski method, Kyropoulos method and HEM (Heat Exchange Method). Out of these, the Kyropoulos method is most commonly used as the method of growing a sapphire single crystal which becomes the material of a large-sized substrate having a diameter of 6 inches or more.

The Kyropoulos method is a type of melt growing method. In this method, a crucible is cooled by gradually reducing the output of a heater without pulling up a seed crystal which has been brought into contact with the liquid surface of a raw material melt or while the seed crystal is pulled up at a much slower speed than that of the Czochralski method to grow a single crystal in an area below the surface of the raw material melt. This Kyropoulos method makes it possible to obtain a large-diameter single crystal having excellent crystal characteristics easily.

However, in the Kyropoulos method, crystal growth is carried out at a very low temperature gradient as compared with that of the Czochralski method. Therefore, crystal growth is greatly affected by the growth speed which differs according to crystal orientation. Therefore, crystal growth is easy with a quick-growth axis as a growth direction whereas crystal growth is difficult with a slow-growth axis as a growth direction. To obtain an ingot by growing a sapphire single crystal by the Kyropoulos method, a crystal is generally grown in the a-axis direction by arranging the c-axis direction having a low growth speed and the property of disseminating a crystal defect perpendicular to the growth direction (refer, for example, to JP-A 2008-207992). To obtain the above r-plane sapphire single crystal substrate from the sapphire ingot with the a-axis as a growth direction which has been obtained as described above, after the ingot is cut in an oblique direction to obtain an r-plane sapphire single crystal core cylindrical body, the step of cutting the cylindrical body into a disk form is required (refer to JP-A 2008-971).

For the above reason, the r-plane sapphire single crystal core cut out from the sapphire ingot obtained by the Kyropoulos method becomes much smaller than the sapphire ingot before cutting. For example, a large-sized crystal which is generally obtained by the Kyropoulos method is a cylindrical body having a diameter of about 200 mm and an a-axis in the height direction. When a cylindrical core having a diameter of 150 mm and a bottom surface as the r-plane is cut out from the cylindrical body, a core having a maximum length of only about 134 mm can be theoretically obtained.

However, a multi-wire saw used to slice a sapphire single crystal core into a substrate is generally a device capable of cutting a core having a length of 300 mm or more. The actual work includes a complicated step in which a plurality of thin cores are interconnected while their orientations are accurately aligned to achieve a total length of, for example, 200 mm or more and then the combined cores are cut so as to improve productivity.

Meanwhile, in crystal growth by the Czochralski method, the difference in growth speed by crystal orientation is small. Therefore, it is relatively easy to grow a sapphire single crystal having a length of 200 mm or more in the r-axis direction. However, when a crystal is grown in the r-axis direction, a flat part called “facet” is often formed in the specific crystal orientation of a shoulder part. When this facet is formed, the crystal shape does not become axially symmetric, thereby causing the entry of a large number of air bubbles into the center part of the crystal. As a result, it is impossible to produce a sapphire single crystal core having a diameter of 150 mm or more and containing no bubbles.

### DISCLOSURE OF THE INVENTION

The present invention was made to overcome the above situation.

It is therefore an object of the present invention to provide a sapphire single crystal core having an axis of r-axis direction and a sufficiently large diameter and a length large enough to use a multi-wire saw and containing no air bubbles as well as a production method thereof.

The inventors of the present invention found that a large-diameter long sapphire single crystal core which has an r-axis crystal growth direction and contains no air bubbles can be produced stably by forming a shoulder part having a specific profile during crystal growth by the Czochralski method. The present invention was accomplished based on this finding.

That is, the present invention is a sapphire single crystal core which has an r-axis direction, a length of 200 mm or more and a diameter of 150 mm or more and contains no air bubbles and a production method thereof

### BRIEF DESCRIPTION OF THE DRAWINGS

FIG. 1 is a schematic diagram of a sapphire single crystal core according to the present invention;

FIG. 2 is a schematic diagram showing the structure of a Czochralski method single crystal pulling device;

FIG. 3 is schematic diagram showing the structure of an annealing furnace;

FIG. 4 shows an example of a sapphire ingot processing step;

FIG. 5 is a diagram showing the profile of the shoulder part of a sapphire single crystal in Example 1; and

FIG. 6 is a diagram showing the profile of the shoulder part of a sapphire single crystal in Comparative Example 1.

### BEST MODE FOR CARRYING OUT THE INVENTION

### <Sapphire Single Crystal Core>

The sapphire single crystal core of the present invention has an axis, of r-axis direction and a length of 200 mm or more and a diameter of 150 mm or more and contains no air bubbles.

The sapphire single crystal core of the present invention has two parallel plane surfaces. The angle formed by the r-axis and each of the above plane surfaces of the sapphire single crystal core of the present invention is 90±1°.

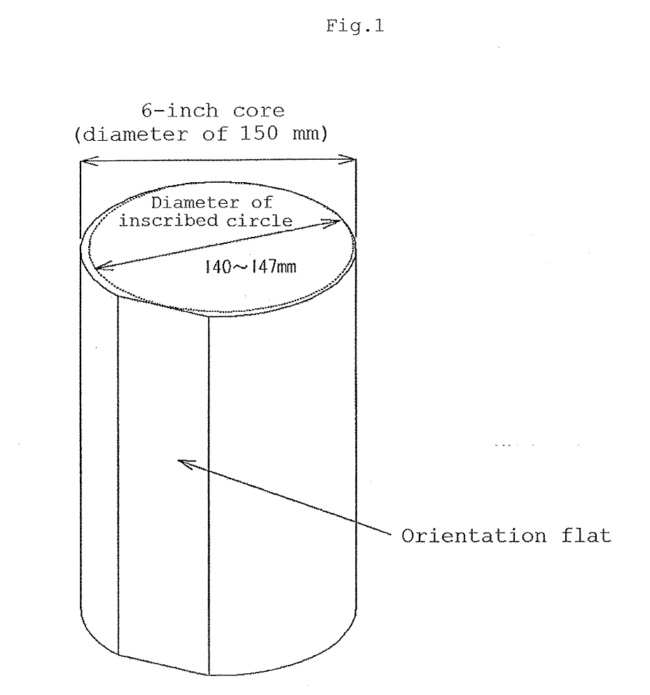

The diameter of the inscribed circle of each of the above two plane surfaces of the sapphire single crystal core of the present invention is 140 mm or more. A notch called “orientation flat” is generally formed in the sapphire single crystal core so as to match the orientations of substrates after slicing (see FIG. 1). The width of the notch is generally 30 to 70 mm. Therefore, in consideration of the existence of this notch, when the diameter of the inscribed circle of each of the above plane surfaces is 140 mm or more, the core itself becomes a large-diameter core for 6 inch (diameter of 150 mm) or more substrates. Although the upper limit of the diameter of the core is not particularly determined, the diameter of the core is preferably 170 mm or less when the suppression of the production of crystal cracks, breakage and lineage in the production process using the Czochralski method and the usefulness of a large diameter are taken into consideration.

The sapphire single crystal core of the present invention has a distance between the above two plane surfaces (length in a direction perpendicular to the two plane surfaces) of 200 mm or more. Although the upper limit of this length is not particularly determined, it is preferably 500 mm or less, more preferably 350 mm or less when the suppression of the production of crystal cracks, breakage and lineage in the production process using the Czochralski method and the usefulness of a large diameter are taken into consideration.

The sapphire core of the present invention is a single crystal and does not have lineage which can be checked by X-ray topography. That is, the sapphire single crystal core of the present invention is a true single crystal or close to it. The measurement conditions of X-ray topography for observing the existence of the above lineage are given below. X-ray measurement instrument: XRT-100 of Rigaku Corporation Measurement system: reflection system

X-ray tube anticathode: Cu
Tube voltage: 50 kV
Tube current: 300 mA
Imaging method: film method
2θ: 89.0°
ω: 102.3°
Entrance slit: curved slit, width of 1 mm
Receiving slit: curved slit, width of 3 mm
Number of scans: 10
Scanning rate: 2 mm/min

In the present invention, when a plane having boundaries which differ in brightness by 16 or more (and grain boundaries associated with this) is not observed in a gray scale image represented by the shading of 256 gradations from brightness 0 (black) to 255 (white) imaged under the above conditions, it is evaluated that the crystal has no lineage. The existence of lineage can be easily judged based on the existence of striae visible by cross-nicol observation in a dark room.

The sapphire single crystal core of the present invention contains no air bubbles. The existence of air bubbles in the sapphire single crystal core can be checked, for example, by visual observation under irradiation from a high-luminance light source in a dark room. The high-luminance light source which can be used herein has a light flux of, for example, 1,000 to 6,000 lm. Examples of the high-luminance light source which can be used to check the existence of air bubbles in the sapphire single crystal core include an LED lamp, halogen lamp and metal halide lamp. Commercially available products thereof include the PCS-UMX250 metal halide lamp of Nippon P•I Co., Ltd. (light flux: about 3,000 lm).

The sapphire single crystal core of the present invention may be made to contain no air bubbles which are checked by observation under the above conditions. According to observation under the above conditions, since air bubbles having a minimum diameter of 10 μm can be observed, the sapphire single crystal core of the present invention does not contain air bubbles having a diameter of 10 μm or more.

### <Production Method of Sapphire Single Crystal Core>

The production method of the sapphire single crystal core of the present invention comprises the steps of:

obtaining a sapphire ingot by growing sapphire single crystals in an r-axis direction by the Czochralski method; and

cutting out a core from the sapphire ingot.

When the shoulder part of the ingot is formed by the above Czochralski method, the shoulder part forming speed must be controlled to ensure that the length in the growth direction of an area where the angle with respect to the horizontal plane (shoulder angle) is 10 to 30° of the shoulder part becomes 10 mm or less. The formation of the facet in the crystal shoulder part can be suppressed by this control, thereby making it possible to obtain a sapphire ingot having a large diameter and a large length without fine air bubbles or lineage. The above sapphire single crystal core can be manufactured by carrying out the heat treatment of this as-grown ingot as required, cutting and grinding/polishing it.

The relationship between setting the length in the growth direction of the area where the shoulder angle is 10 to 30° to 10 mm or less and the formation of the facet can be considered as follows.

The facet at the time of growing a single crystal is formed when a surface in a slow crystal growth direction becomes flat. In the sapphire single crystal, the facet is readily formed on the c-plane with slowest growth. In fact, when crystal growth is carried out in the r-axis direction as a pulling direction, the plane orientation of the facet which appears in the shoulder part is a c-plane (angle formed with the horizontal plane is 57.6°). When the c-plane facet grows, the shape of the crystal interface (interface between a crystal and a melt) does not become point-symmetrical. A convection of the melt is disturbed by this unsymmetrical crystal interface, whereby air bubbles are mixed into a growing single crystal.

Research into this conducted by the inventors of the present invention revealed that when crystal growth is carried out in the r-axis direction as the pulling direction, the c-plane facet is not formed in an area where the shoulder angle is less than 10° and an area where the shoulder angle is more than 30°. Therefore, when a crystal is grown with a profile having no area with a should angle of 10 to 30°, a single crystal having no facet must be obtained. However, to actually grow a single crystal having no area with a shoulder angle of 10 to 30°, there is only a method in which the shoulder angle is set larger than 30° from the beginning of pulling up a crystal. To expand the crystal diameter to 150 mm or more with this profile, a very long shoulder part is required, which is inconvenient from the viewpoint of productivity. Then, when the inventors of the present invention tried to find a realistic way through elaborate studies and investigations, they found that a large-diameter long sapphire single crystal core having an r-axis as a crystal growth direction and containing no air bubbles can be manufactured stably by setting the length in the growth direction with a shoulder angle of 10 to 30° to 10 mm or less.

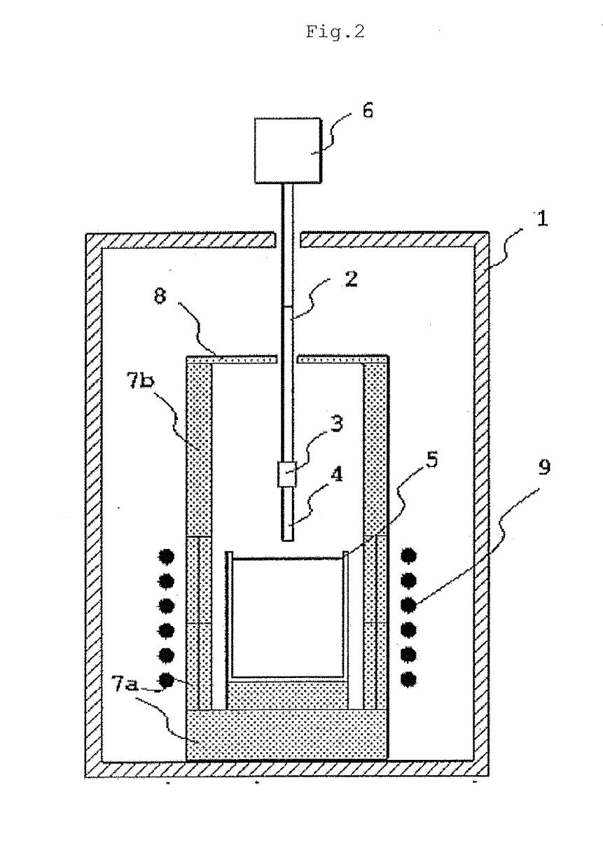

FIG. 2 shows an example (schematic diagram) of a single crystal pulling device used to manufacture the sapphire single crystal core of the present invention by the Czochralski method.

This single crystal pulling device has a chamber 1 constituting a crystal growth furnace. A single crystal pulling rod 2 is suspended from the upper wall of the chamber 1 through an opening. A seed crystal 4 is attached to the distal end of the single crystal pulling rod 2 by a seed crystal holding tool 3. The seed crystal 4 is arranged on the center axis of a crucible 5. A load cell 6 for measuring the weight of a crystal is mounted on the upper end of the above single crystal pulling rod 2. The above single crystal pulling rod 2, the holding tool 3, the seed crystal 4 and the load cell 6 can be moved up and down and turned by an unshown drive apparatus.

A crucible having a known shape and made of a known material which is used in the Czochralski method may be used as the crucible 5. As for the shape of the crucible, in general, a crucible which has a circular opening when seen from the top, a cylindrical body part and a bottom which is planar, shaped like a bowl or inverse conical shaped is advantageously used. As for the material of the crucible, a material which withstands a temperature at which aluminum oxide as the raw material is molten and has low reactivity with aluminum oxide is suitable. More specifically, iridium, molybdenum, tungsten, rhenium and alloys of two or more thereof are generally used. Iridium or tungsten having excellent heat resistance is preferably used.

A heat insulating wall 7a is arranged to surround the bottom and outer wall of the crucible below and around the crucible. A heat insulating wall 7b is installed around the side wall of a single crystal pulling area above the crucible. Any known heat insulating material or any heat insulating structure may be used for the above heat insulating walls 7a and 7b without restriction. Examples of the heat insulating material include zirconia-based materials, hafnium-based materials, alumina-based materials and carbon-based materials. The zirconia-based materials and hafnium-based materials may be stabilized materials obtained by adding yttrium, calcium or magnesium. As the heat insulating structure, reflection materials may be advantageously used. Laminates of metal sheets made of tungsten or molybdenum are such examples.

Since the heat insulating walls 7a and 7b are used in an environment in which the difference between the inside temperature and the outside temperature is extremely large, their materials are apt to be deformed significantly and cracked by repetitions of heating and cooling. When the temperature gradient of the crystal growth area is changed by the deformation and cracking of the heat insulating walls, stable crystal production becomes difficult. Then, it is preferred to suppress such deformation and cracking by combining several divided heat insulating materials to construct the heat insulating walls and not making the heat insulating walls from a single material. According to this, the change of the temperature gradient of the crystal growth area can be suppressed as much as possible advantageously.

The opening at the upper end of the heat insulating wall surrounding the single crystal pulling area is closed by a ceiling plate 8 having an insertion hole for the single crystal pulling rod 2. Thereby, the single crystal pulling area is situated within a single crystal pulling room formed by the above heat insulating walls 7a and 7b and the ceiling plate 8 with the result of greatly increased heat retention. The above ceiling plate 8 may be formed from a similar known heat insulating material to the heat insulating walls or of a heat insulating structure. The above ceiling plate 8 does not need to be shaped like a plate and may have any shape as long as the opening at the upper end of the surrounding heat insulating wall is closed except for the insertion hole. Besides the plate-like shape, it may be truncated cone-shaped, inverse truncated cone-shaped, conical hat-shaped, inverse conical hat-shaped, dome-shaped or inverse dome-shaped.

A high-frequency coil 9 is arranged around the heat insulating wall up to the same height as the crucible. The high-frequency coil is connected to an unshown high-frequency power source. The high-frequency power source is connected to a control unit composed of a computer so as to suitably control its output. In general, the control unit controls the output of the high-frequency power source by analyzing the weight change of the load cell as well as the rotation speeds of the crystal pulling shaft and the crucible, the pulling rate and the operation of a valve for gas inflow/outflow.

When the sapphire single crystal core is used for a sapphire substrate for semiconductors, aluminum oxide (alumina) having a purity of 4N (99.99%) or more is generally used as the raw material. Since an impurity enters a space between lattices of a sapphire single crystal or into a lattice to become the starting point of a crystal defect, when a raw material having low purity is used, lineage tends to occur in the crystal, and the crystal tends to be colored. The cause of coloring a crystal is a color center caused by a crystal defect formed by an impurity. Therefore, the coloring of a crystal indicates the number of crystal defects indirectly. Since chromium as an impurity in particular has a great influence on the coloring of a crystal, a raw material having a chromium content of less than 100 ppm is preferably used. When a raw material having a high bulk density is used, the amount (weight) of the raw material charged into the crucible can be increased, thereby making it possible to suppress the scattering of the raw material in the furnace. The bulk density of the raw material is preferably 1.0 g/mL or more, more preferably 2.0 g/mL or more. Examples of the raw material having such properties include products obtained by granulating aluminum oxide powers with a roller press and ground sapphire (crackled or crushed sapphire).

For the production of the sapphire single crystal core, the above raw material is first injected into the above crucible installed in the above crystal growth furnace and heated to obtain a raw material melt. The temperature elevation rate until the raw material reaches a molten state is not particularly limited but preferably 50 to 200° C./hr. When this temperature elevation rate is too fast, the crucible may be damaged due to the production of a marked heat distribution in the crucible. Meanwhile, when the temperature elevation rate is too slow, productivity is impaired disadvantageously.

After the raw material reaches a molten state, the seed crystal 4 attached to the seed crystal holding tool 3 at the distal end of the crystal pulling shaft is lowered to be brought into contact with the surface of the raw material melt and then gradually pulled up to grow a single crystal. When the seed crystal is pulled up, the temperature of the raw material melt in contact with the seed crystal is preferably set slightly lower (supercooling temperature) than the melting point of the raw material for the stable growth of a crystal without causing abnormal growth. To grow a sapphire single crystal, the seed crystal is preferably pulled up at a temperature range from 2,000° C. to 2,050° C.

The seed crystal to be pulled up is a sapphire single crystal and the vertical direction of its end in contact with the surface of the raw material melt is an r-axis. Since the quality of a single crystal obtained by crystal growth greatly depends on the quality of the seed crystal, special attention is required for the selection of the quality of the seed crystal. It is desired that the seed crystal should have a minimum number of crystal defects and a minimum number of imperfect parts of the crystal structure called “transitions”. Whether the crystal structure is good or not can be evaluated by using a suitable method such as the etch pit density measurement, AFM or X-ray topography of the distal end face or a part in the vicinity thereof of the seed crystal. Since the number of crystal defects tends to become larger as the residual stress becomes greater, the selection of a seed crystal having small stress by means of cross-nicol observation and stress birefringence measurement is also effective.

Although the shape of the distal end part in contact with the raw material melt of the seed crystal is not particularly limited, the distal end part is particularly preferably an r-plane flat surface. Although the shape of the whole seed crystal is not particularly limited, it is preferably columnar or square columnar. At least one means selected from an expanded part, a constricted part and a through hole to be held by the holding tool 3 is generally formed in the top part of the seed crystal.

When the seed crystal is lowered to be brought into contact with the surface of the raw material melt, the descending rate of the seed crystal is preferably 0.1 to 100 mm/min, more preferably 1 to 20 mm/min.

When the seed crystal is lowered to be brought into contact with the surface of the raw material melt and when crystal growth is carried out by gradually pulling up the seed crystal, at least one of the seed crystal and the crucible is preferably turned. The relative rotation speeds of the seed crystal and the crucible in these cases are preferably 0.1 to 30 rpm.

After the seed crystal is brought into contact with the raw material melt, a shoulder part (diameter expansion part) is formed by pulling up the seed crystal while the pulling rate of the seed crystal, the relative rotation speeds of the seed crystal and the crucible, and the output of the high-frequency coil are suitably controlled, and after the crystal diameter is expanded to a desired value, the seed crystal is pulled up to maintain the expanded crystal diameter. When the pulling rate is too slow, productivity is impaired and when the pulling rate is too fast, variations in the growth environment become too large, whereby polycrystalization may occur, or lineage or small air bubbles may be formed. Therefore, to achieve high productivity and high crystal quality at the same time, the pulling rate of the seed crystal at the time of forming the shoulder part and the pulling rate of the seed crystal after the crystal diameter is expanded to a desired value are preferably 0.1 to 20 mm/hr, more preferably 0.5 to 10 mm/hr, much more preferably 1 to 5 mm/hr.

The method of the present invention requires the control of the forming speed of the above shoulder part to ensure that the length in the growth direction of the area where the shoulder angle is 10 to 30° becomes 10 mm or less. The length in the growth direction of the area is preferably 2 mm or more. When this value is set excessively small, the crystal shape is disturbed by a quick change in the output of the heater at the time of changing the shoulder angle, whereby such troubles as the entry of bubbles into a growing crystal or polycrystalization may occur disadvantageously. The ratio of the length in the growth direction of an area where the shoulder angle is less than 10° and the length in the growth direction of an area where the shoulder angle is more than 30° is not particularly limited and may be arbitrary. When the ratio of the length in the growth direction of the area where the shoulder angle is more than 30° is made large, the total length of the shoulder becomes large inevitably. Therefore, in this embodiment, the length of the straight body part which can be used as the core becomes small relative to the total length of the crystal, thereby reducing productivity. From this point of view, the length in the growth direction of the area where the shoulder angle is more than 30° is preferably set to less than 0.5 times the diameter of the straight body part of the grown crystal.

What the diameter of the crystal is expanded to is determined by what size of the single crystal is to be produced. In crystal growth by the Czochralski method, the probability of the production of lineage or small air bubbles becomes higher as the diameter of the crystal becomes larger. Therefore, to mass-produce 6-inch SOS substrates while the production of crystal cracking/breakage and lineage is suppressed, the diameter of the crystal is preferably set to 150 to 170 mm.

The inside pressure of the furnace during the pulling of the single crystal may be increased pressure, normal pressure or reduced pressure but it is easy to carry out the pulling of the single crystal at normal pressure. The atmosphere is preferably an inert gas atmosphere such as helium, nitrogen or argon atmosphere; or an atmosphere obtained by containing 10 vol % or less of oxygen in the inert gas.

The sapphire single crystal core produced by the method of the present invention is cut with a multi-wire saw to be used as an SOS substrate. Therefore, the sapphire single crystal core preferably has a straight body part length which can be cut with the multi-wire saw efficiently. From this point of view, the length of the straight body part of the single crystal which is to be cut out of the sapphire single crystal core needs to be 200 mm or more, preferably 250 mm or more. When the length of the straight body part is less than 200 mm, to cut the sapphire single crystal core with the multi-wire saw efficiently, an additional step for interconnecting a plurality of cores by matching their orientations precisely to achieve a total length of 200 mm or more and cutting them with a multi-wire saw is required, thereby reducing production efficiency and increasing production cost disadvantageously. When the length of the straight body part is made more than 500 mm, the temperature environmental changes of the crystal growth area in the furnace during crystal growth become too large, whereby stable growth tends to become difficult disadvantageously.

After the sapphire ingot (single crystal) is pulled up, the single crystal is separated from the raw material melt. The method of separating the single crystal is not particularly limited. For example, it is separated by increasing the output of a heater (an increase in the temperature of the raw material melt), raising the crystal pulling rate, or lowering the crucible. Separation may be carried out by any one of these methods or a combination of two or more thereof.

Prior to separation, in order to minimize a temperature change (heat shock) at a moment when the single crystal separates from the raw material melt, it is effective to carry out a tail treatment for gradually reducing the diameter of the crystal. This tail treatment may be carried out by gradually increasing the output of the heater or gradually raising the crystal pulling rate.

The single crystal separated from the raw material melt is cooled to a temperature at which it can be taken out from the furnace. The productivity of the crystal growth step can be increased by raising the cooling rate. However, when the cooling rate is too fast, stress distortion remaining in the single crystal grows, whereby cracking or fracture may occur at the time of cooling or in the post-step, or abnormal warpage may occur in a substrate which is a final product. When the cooling rate is too slow, the productivity of the crystal growth step decreases. In consideration of these, the cooling rate is preferably set to 10 to 200° C./hr.

A sapphire ingot which is a single crystal having an r-axis growth direction and a straight body part with a desired diameter and a desired length can be manufactured as described above.

The sapphire ingot manufactured as described above may be subjected to a heat treatment (annealing) as required after that. The purpose of this heat treatment is to prevent cracking at the time of cutting, reduce stress in the crystal and improve a crystal defect and coloring.

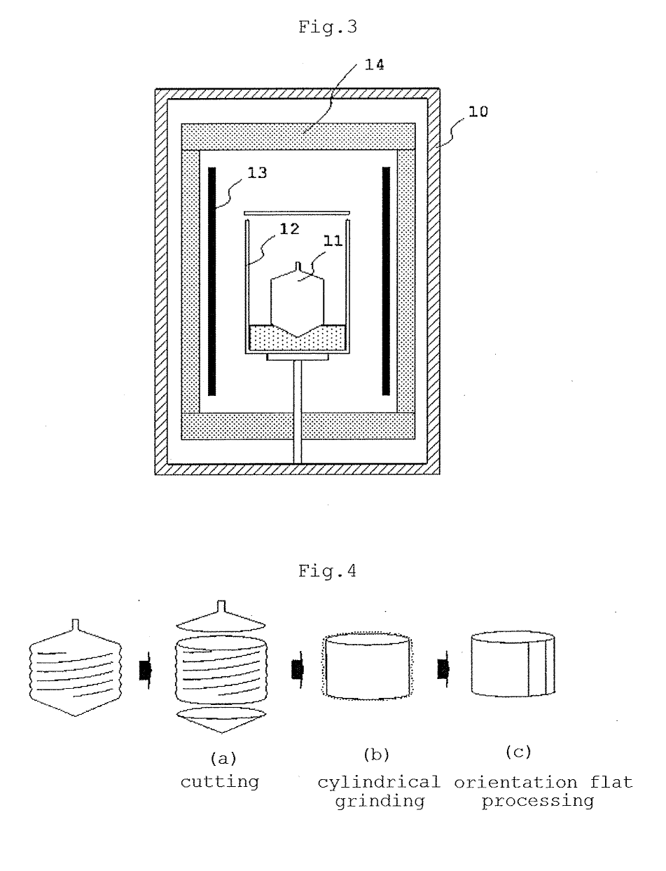

FIG. 3 shows an example (schematic diagram) of an annealing device used for this heat treatment.

In this annealing device, a vessel 12 for storing a single crystal 11 is installed in a chamber 10, and a heating body 13 is arranged around this vessel. The vessel 12 for storing a single crystal and the heating body 13 are stored in a temperature retention area constituted by a heat insulating wall 14 surrounding a ceiling part, a bottom part and an outer wall.

Any material which withstands the temperature and atmosphere of the heat treatment may be used as the material of the vessel 12 for storing an ingot. Examples of the material include metal materials, oxide materials, nitride materials and other heat insulating materials. The metal materials include iridium, molybdenum, tungsten, rhenium and alloys thereof. The above oxide materials include zirconia-based materials, hafnium-based materials and alumina-based materials. Out of these, zirconia-based materials and hafnium-based materials may be stabilized materials obtained by adding yttrium, calcium or magnesium. The above nitride materials include boron nitride materials and aluminum nitride materials; and the other heat insulating materials include carbon heat insulating materials.

Means for installing the single crystal 11 in the vessel 12 is not particularly limited, and known means may be suitably selected and used. One example of the means is a method in which aluminum oxide powders are spread over the bottom of the vessel 12 and the shoulder or tail part of the single crystal is buried in the powders.

The heating body 13 for heating the temperature retention area to a desired temperature may be a heating body employing known heating system. Stated more specifically, heating up to 2,000° C. can be carried out stably by employing resistance heating system using carbon or tungsten as a heating body advantageously.

As the material of the heat insulating wall 14 constituting the temperature retention area, a known heat insulating material which withstands the temperature of the heat treatment and has no atmospheric reactivity and no atmospheric corrosion may be selected and used. For example, heat insulating materials composed of oxide-based materials and other materials may be used. The above oxide-based materials include zirconia-based materials, hafnium-based materials and alumina-based materials. Out of these, zirconia-based materials and hafnium-based materials may be stabilized materials obtained by adding yttrium, calcium or magnesium. The other materials include carbon materials. When an oxide material is used as the material of the heat insulating wall 14, the atmosphere is preferably made an inert atmosphere or an oxidation atmosphere; and when a carbon material is used, the atmosphere is preferably made an inert atmosphere or a reducing atmosphere. The oxide material may react in the reducing atmosphere to become fragile or release an impurity containing a metal atom; and the carbon material may react in the oxidation atmosphere to become fragile or burn.

At the time of heating the sapphire ingot, the ambient atmosphere, the temperature elevation rate, the highest reach temperature, the retention time at the highest reach temperature and the cooling rate after retention at the highest reach temperature may be suitably set according to purpose.

For example, to prevent cracking at the time of cutting and reduce stress in the crystal, preferably, the temperature elevation rate is set to 20 to 200° C./hr, the highest reach temperature is set to 1,400 to 2,000° C., the retention time at the highest reach temperature is set to 6 to 48 hours, and the cooling rate is set to 1 to 50° C./hr under evacuation or an arbitrary atmosphere. The arbitrary atmosphere is, for example, an inert atmosphere, oxidation atmosphere or reducing atmosphere. The above inert atmosphere may be realized by using an inert gas such as helium, nitrogen or argon; the above oxidation atmosphere may be realized by using air or a mixed gas of air and oxygen; and the above reducing atmosphere may be realized by using hydrogen or a mixed gas of hydrogen and an inert gas (such as helium, nitrogen or argon).

To improve a crystal defect and coloring, preferably, the highest reach temperature is set to 1,400 to 1,850° C., and the retention time at the highest reach temperature, the temperature elevation rate and the cooling rate may be set arbitrarily under evacuation, oxidation atmosphere or reducing atmosphere. The oxidation atmosphere may be realized by using air, oxygen, an inert gas (such as helium, nitrogen or argon) containing 1 to 99 vol % of oxygen, or a mixed gas containing 21 to 99 vol % of oxygen and air; and the above reducing atmosphere may be realized by using hydrogen or an inert gas (such as helium, nitrogen or argon) containing 1 to 99 vol % of hydrogen. When the ambient atmosphere at the time of the heat treatment is a condition other than vacuum evacuation, the pressure is preferably 0.1 Pa to 150 kPa.

The as-grown sapphire ingot manufactured as described above or the sapphire ingot which has been arbitrarily subjected to the heat treatment as described above can be formed into a sapphire single crystal core by suitably selecting and using known cutting and grinding steps.

FIG. 4 shows an example of the step of processing a sapphire ingot into a sapphire single crystal core.

The shoulder part and tail part of the sapphire ingot are first cut off, leaving the straight body part behind (FIG. 4 (a)). Then, cylindrical grinding is carried out to remove irregularities on the side wall of the straight body part so as to make the sapphire single crystal core cylindrical with a constant diameter (FIG. 4 (b)). Further, a flat part called “orientation flat” is formed in the specific orientation of the side wall of the straight body part, thereby making it possible to obtain a sapphire single crystal core (FIG. 4 (c)).

Cutting means in the cutting step shown in FIG. 4 (a) is not limited, and suitable cutting means such as a cutting blade, high-pressure water or laser may be used. Out of these, the cutting means is preferably a cutting blade; more preferably a cutting blade such as an inner peripheral blade, outer peripheral blade, band saw or wire saw; particularly preferably an endless cutting blade such as a band saw or wire saw.

The sapphire single crystal core of the present invention can be obtained as described above.

Since the sapphire single crystal core of the present invention can be cut with an ordinary multi-wire saw without requiring an addition step such as joining, it can contribute to the efficient production of an r-plane sapphire substrate.

### EXAMPLES

### Example 1

50 kg of high-purity alumina having a purity of 4N (99.99%) (AKX-5 of Sumitomo Chemical Co., Ltd.) was injected as a raw material into an iridium crucible having an inner diameter of 265 mm and a depth of 310 mm. This crucible was placed in a Czochralski crystal pulling furnace having a heater of high-frequency induction heating system. After the inside of the furnace was evacuated to 100 Pa or less, a nitrogen gas containing 1.0 vol % of oxygen was introduced into the furnace to raise the inside pressure of the furnace to atmospheric pressure. After the inside pressure of the furnace reached atmospheric pressure, the inside of the furnace was evacuated while a gas having the same composition as above was introduced into the furnace at a rate of 2.0 L/min to keep the inside pressure of the furnace at atmospheric pressure.

The heating of the crucible was started to gradually raise the temperature over 9 hours until alumina in the crucible reached its melting temperature.

After the temperature of the crucible reached the alumina melting temperature, the output of the heater was adjusted to achieve a stable state that convection (spoke pattern) on the surface of the alumina melt changed very slowly. Then, a seed crystal which was a square columnar sapphire single crystal having an r-plane end was gradually lowered while it was turned at 1 rpm to bring the end of the seed crystal into contact with the surface of the alumina melt. After the output of the heater was further finely adjusted to ensure that the seed crystal did not melt and a crystal did not grow on the surface of the alumina melt, the pulling of the seed crystal was started at a pulling rate of 2 mm/hr.

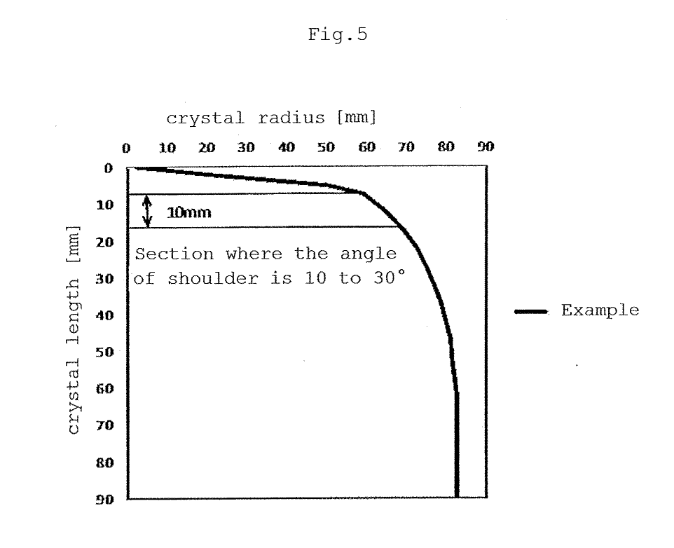

While the pulling rate of the seed crystal was kept at 2 mm/hr, crystal growth was carried out by suitably adjusting the output of the heater to ensure that the diameter of the crystal estimated from a change in the load of the load cell became a predetermined value. At this point, in the step of expanding the diameter of the crystal to 155 mm (the step of forming a shoulder part), crystal growth was carried out to ensure that the length in the growth direction of the area where the angle with respect to the horizontal plane was 10 to 30° became 10 mm. The profile of the shoulder part of the crystal formed herein is shown in FIG. 5.

After the diameter of the crystal became 155 mm, the shoulder angle was smoothly increased to expand the diameter to 165 mm so that the profile of the shoulder part became a curved line shown in FIG. 5. Thereafter, the pulling rate was raised to 3 mm/hr to pull up the crystal continuously while the diameter of the crystal was kept at 160 to 170 mm.

After the length of the straight body part became 300 mm, the tail treatment was carried out by gradually raising the output of the heater, and the pulling rate was further raised to 10 mm/min to separate the single crystal from the alumina melt.

The obtained single crystal was cooled to room temperature over 30 hours.

By the above operation, a sapphire ingot (single crystal) whose axial direction was an r-axis, whose diameter was controlled to 160 to 170 mm and whose straight body part had a length of 300 mm was obtained. A clear c-plane facet was not observed in the shoulder part of this ingot. When this ingot was visually observed under irradiation from a metal halide lamp (PCS-UMX250 of Nippon P•I Co., Ltd., light flux: about 3,000 lm) in a dark room, no air bubbles were seen in the crystal. No striae were seen even by visual cross-nicol observation.

Then, the above ingot was installed in the temperature retention area of an ingot annealing device and heated up to 1,600° C. over 20 hours while an argon gas was flown at a rate of 3 L/min. Thereafter, the ingot was kept at a temperature of 1,600° C. for 24 hours and then cooled to room temperature over 35 hours.

The upper part (shoulder part) and lower part (tail part) of the crystal ingot which has been annealed were cut off with a band saw, and the upper and lower cut faces of the straight body part were made r-plane by using a planar grinding device. After the ingot was made cylindrical with a diameter of 150 mm by a cylindrical grinding device, an orientation flat was formed on the side face so as to obtain a sapphire single crystal core having an r-axis direction, a diameter of 150 mm and a length of 300 mm and containing no air bubbles.

### Comparative Example 1

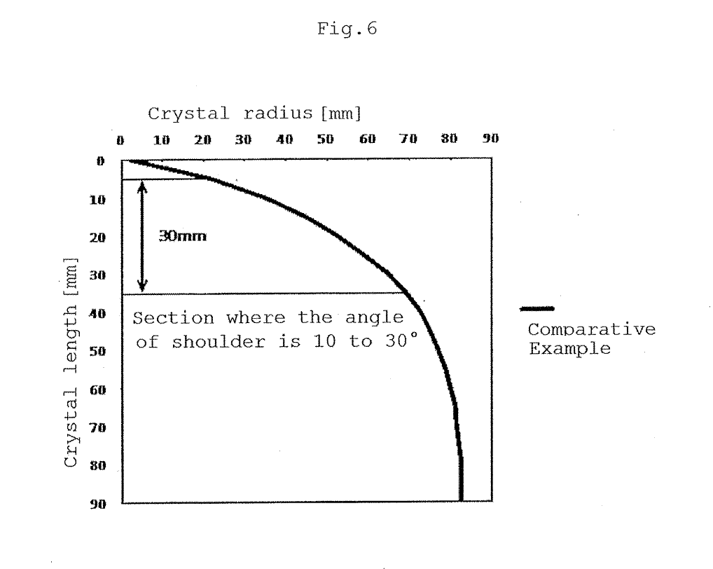

A sapphire ingot whose axial direction was an r-axis, whose diameter was controlled to 160 to 170 mm and whose straight body part had a length of 300 mm was obtained by carrying out crystal growth in the same manner as in Example 1 except that the length in the growth direction of the area where the angle with respect to the horizontal plane was 10 to 30° was changed to 30 mm in the diameter expanding step in the above Example 1. The profile of the shoulder part of the crystal formed herein is shown in FIG. 6.

A c-plane facet was observed in the area where the angle with respect to the horizontal plane was 10 to 30° of the shoulder part of this single crystal. A large number of air bubbles were seen in the vicinity of the center of the straight body part of this ingot by visual observation under irradiation from a metal halide lamp in a dark room. No striae were seen by visual cross-nicol observation.

The obtained single crystal was annealed, cut and ground in the same manner as in Example 1 to obtain a sapphire single crystal core which had an r-axis direction and a diameter of 150 mm and a length of 300 mm. However, a large number of air bubbles were existent in the sapphire single crystal core.

### EXPLANATION OF REFERENCE NUMERALS

1: chamber
2: single crystal pulling rod
3: seed crystal holding tool
4: seed crystal
5: crucible
6: load cell
7a, 7b: heat insulating wall
8: ceiling plate
9: high-frequency coil
10: chamber
11: ingot
12: vessel
13: heating body
14: heat insulating wall

### EFFECT OF THE INVENTION

According to the present invention, a sapphire single crystal core having an r-axis direction, a length of 200 mm or more and a diameter of 150 mm or more and containing no air bubbles and no lineage can be easily manufactured. By using this sapphire single crystal core, efficient cutting with a multi-wire saw is made possible without a complicated step of interconnecting cores. Therefore, the production efficiency of an r-plane sapphire substrate can be greatly improved by the present invention.

1. A sapphire single crystal core having an axis of r-axis direction, a length of 200 mm or more and a diameter of 150 mm or more and containing no air bubbles.

2. The sapphire single crystal core according to claim 1, wherein the air bubbles are visible by observation under irradiation from a high-luminance light source in a dark room.

3. A method of producing the sapphire single crystal core of claim 1, comprising the steps of:
obtaining a sapphire ingot by growing a sapphire single crystal in an r-axis direction by the Czochralski method; and
cutting out the core from the sapphire ingot, wherein
when the shoulder part of the ingot was formed by the Czochralski method, the shoulder part forming speed is controlled to ensure that the length in the growth direction of an area where the angle with respect to the horizontal plane is 10 to 30° of the shoulder part becomes 10 mm or less.

4. The method according to claim 3, wherein the length in the growth direction of the area where the angle with respect to the horizontal plane is 10 to 30° of the shoulder part is 2 mm or more.

5. A method of producing the sapphire single crystal core of claim 2, comprising the steps of:
obtaining a sapphire ingot by growing a sapphire single crystal in an r-axis direction by the Czochralski method; and
cutting out the core from the sapphire ingot, wherein
when the shoulder part of the ingot was formed by the Czochralski method, the shoulder part forming speed is controlled to ensure that the length in the growth direction of an area where the angle with respect to the horizontal plane is 10 to 30° of the shoulder part becomes 10 mm or less.

6. The method according to claim 5, wherein the length in the growth direction of the area where the angle with respect to the horizontal plane is 10 to 30° of the shoulder part is 2 mm or more.
